(19) United States
(12) Patent Application Publication
(10) Pub. No.: US 2026/0130025 A1
(43) Pub. Date: May 7, 2026

(54) PACKAGING STRUCTURE, SYSTEM, AND METHOD

(71) Applicant: Aivres Systems Inc., Fremont, CA (US)

(72) Inventor: Chunghsing Han, New Taipei City (TW)

(73) Assignee: Aivres Systems Inc., Fremont, CA (US)

(21) Appl. No.: 19/436,016

(22) Filed: Dec. 30, 2025

(51) Int. Cl. H10H 29/20

(52) U.S. Cl. CPC H10H 29/20

(57) ABSTRACT

A packaging structure, system(s), and method(s) for packaging electronic element(s) are provided. The packing structure is disposed on a substrate (e.g., a circuit board) and includes a transistor, a first resistor, and a first light-emitting element. The packaging structure further includes a first heat-dissipation layer sandwiched between the transistor and the first resistor, and a second heat-dissipation layer sandwiched between the first resistor and the first light-emitting element. Additionally or alternatively, an additional packaging structure is disposed on the circuit board. The additional packaging structure includes a second resistor, a second light-emitting element, and a third heat-dissipation layer sandwiched between the second resistor and the second light-emitting element. The packaging structure may be electrically connected to the additional packaging structure, such that the first and/or second light-emitting element provide indicator light(s) for a component (e.g., a storage drive) hosted by the substrate (e.g., the circuit board).

### TECHNICAL FIELD

The present disclosure relates generally to packaging, and more particularly, to systems and methods for packaging one or more electronic elements (e.g., circuit elements).

### BACKGROUND

An electronic system often includes multiple electronic elements. For example, the electronic system may be a server device that includes a hard drive and a LED lighting element that indicates a state of the hard drive. For the electronic system (or a portion thereof) that has a limited size or to have a reduced size, there is a need to reduce the packaging volume of one or more electronic elements or a circuit that includes the one or more electronic elements (e.g., the LED lighting element).

### SUMMARY

Techniques are described herein for packaging structures and methods that reduce packaging volume of one or more electronic elements. The one or more electronic elements can include, for instance, one or more transistors, one or more resistors, and/or one or more light-emitting elements that form part of a circuit (e.g., an illumination circuit). The packaging structures according to one or more embodiments can include multi-layer structure(s), which allows a circuit board to have more space to accommodate more packaging structures (e.g., when more status indicators are desired).

According to one aspect of the present disclosure, a packaging structure is provided. The packaging structure may include: a transistor; a resistor; a first heat-dissipation layer sandwiched between the transistor and the resistor; a light-emitting element; and/or a second heat-dissipation layer sandwiched between the first resistor and the first light-emitting element.

In some embodiments, the resistor is connected to the light-emitting element via a first conductive element. The light-emitting element can be a single-color LED or a dual-color LED for indicating a state of a component (e.g., a storage device). In some embodiments, the transistor is disposed on a circuit board. In some embodiments, the packaging structure includes a first pin connecting the transistor with the circuit board. For example, the first pin can be a conductive strip included in or coupled to the transistor, where a first end of the first pin connects a gate of the transistor and a second end of the first pin is soldered onto the circuit board to receive a control signal (e.g., via a conductive trace that transmits/carries the control signal). In some embodiments, the control signal is configured to control the light-emitting element to indicate a status (e.g., “on,” “off,” etc.) of an electronic component hosted by the circuit board. In some embodiments, the circuit board is a backplane that includes a connector for connection with the electronic component. In some other embodiments, the circuit board may be a motherboard, or any other applicable board or substrate. In some embodiments, the electronic components can be, for instance, a storage device (e.g., HDD inserted to a slot of the circuit board), or any other applicable component.

In some embodiments, the transistor includes a second pin connecting to a source of the transistor, where the second pin of the transistor is soldered onto the circuit board for connection to ground. In some embodiments, the packaging structure further includes a conductive connector that connects the resistor to the circuit board.

In some embodiments, the transistor is connected (e.g., electrically) to the light-emitting element via a second conductive element. For example, the transistor includes a drain that is connected to the light-emitting element via the second conductive element.

In some embodiments, the packaging structure further includes one or more support elements to support the second heat-dissipation layer. The one or more support elements may be sandwiched between the first and second heat-dissipation layers. In some embodiments, the one or more support elements include a plurality of tapered columns spaced apart from each other and disposed around a periphery of the first or second heat-dissipation layer.

In some embodiments, the first or second heat-dissipation layer may each include an insulating material (e.g., aluminum-based, ceramic-based, etc.). In some embodiments, the first heat-dissipation layer may include a first insulating material, and the second heat-dissipation layer may include a second insulating material. The first insulating material may be the same as, or different from, the second insulating material. In some embodiments, the first or second insulating material may each include a porous structure.

According to another aspect of the present disclosure, a packaging structure is provided. The packaging structure includes: a transistor disposed on a substrate (e.g., a circuit board); a resistor; a heat-dissipation groove that accommodates the resistor; and a light-emitting element disposed above the heat-dissipation groove. In some embodiments, the heat-dissipation groove includes a bottom portion and a side wall portion. In some embodiments, the bottom portion of the heat-dissipation groove is sandwiched between the transistor and the resistor.

In some embodiments, the packaging structure further includes: a heat-dissipation layer disposed between the light-emitting element and the resistor (that is accommodated in the heat-dissipation groove).

In some embodiments, the side wall portion of the heat-dissipation groove includes one or more side walls substantially perpendicular to the bottom portion. In some embodiments, the side wall portion of the heat-dissipation groove includes an opening that allows a first connecting element (e.g., a conductive wire, a conductive strip, etc.) to connect the resistor with the circuit board via the opening. In some embodiments, the heat-dissipation groove further accommodates a second connecting element (e.g., a conductive wire, a conductive strip, etc.) that connects the resistor with the light-emitting element. In some embodiments, the packaging structure further includes a third connecting element (e.g., a conductive wire, a conductive strip, etc.) that connects the transistor with the light-emitting element. The first, second, or third connecting element may be conductive and/or may be covered with an insulating layer (e.g., plastic, etc.)

According to another aspect of the present disclosure, a packaging method is provided. The packaging method includes: disposing a transistor on a substrate (e.g., a circuit board); disposing a first heat-dissipation layer or a heat-dissipation groove over the transistor; disposing a resistor over the first heat-dissipation layer or within the heat-dissipation groove; and disposing a light-emitting element over the resistor or the heat-dissipation groove. In some embodiments, the light-emitting element is separated from the resistor using a second heat-dissipation layer or the heat-dissipation groove.

In some embodiments, the packaging method further includes, prior to disposing the light-emitting element: configuring a first end of a first conductive element to connect with the resistor; configuring a second end of the first conductive element to be connected to a first soldering region disposed on a surface of the second heat-dissipation layer that faces away from the resistor; configuring a first end of a second conductive element to connect with the transistor; and configuring a second end of the second conductive element to be connected to a second soldering region disposed on the surface of the second heat-dissipation layer that faces away from the resistor, the second soldering region being separate from the first soldering region.

### BRIEF DESCRIPTION OF THE DRAWINGS

Systems and methods of the present disclosure are described in detail below with reference to the attached drawing figures, wherein:

FIG. 1 illustrates a block diagram of an example of a system according to one or more embodiments of the present disclosure.

FIG. 2 illustrates block diagrams each showing a section of a backplane that includes one or more status indicators.

FIG. 3 illustrates a block diagram of an electronic system including one or more circuit boards.

FIG. 4A illustrates a schematic diagram of an example of a portion of a circuit, according to one or more embodiments of the present disclosure.

FIG. 4B illustrates an example packaging structure for the portion of the circuit in FIG. 4A, according to one or more embodiments of the present disclosure.

FIG. 5A illustrates an example of a layered packaging structure for the portion of the circuit in FIG. 4A, according to one or more embodiments of the present disclosure.

FIG. 5B illustrates another example of a layered packaging structure for the portion of the circuit in FIG. 4A, according to one or more embodiments of the present disclosure.

FIG. 5C illustrates yet another example of a layered packaging structure for the portion of the circuit in FIG. 4A, according to one or more embodiments of the present disclosure.

FIG. 5D illustrates a top view of a further example of a layered packaging structure for the portion of the circuit in FIG. 4A, according to one or more embodiments of the present disclosure.

FIG. 5E illustrates top views for different configurations of a side wall portion for a heat-dissipation groove, according to one or more embodiments of the present disclosure.

FIG. 6 illustrates a method for packaging one or more electronic elements, according to one or more embodiments of the present disclosure.

FIG. 7 illustrates another method for packaging one or more electronic elements, according to one or more embodiments of the present disclosure.

FIG. 8 illustrates a further method for packaging one or more electronic elements, according to one or more embodiments of the present disclosure.

### DETAILED DESCRIPTION

The following detailed description is exemplary in nature and is not intended to limit the disclosure or the application and uses of the described embodiments. Furthermore, there is no intention to be bound by any expressed or implied theory presented in the preceding background, summary and brief description of the drawings, or the following detailed description. Numerous specific details are set forth in order to provide a more thorough understanding of the disclosed technology. However, it will be apparent to one of ordinary skill in the art that the disclosed technology may be practiced without these specific details. In other instances, well-known features have not been described in detail to avoid unnecessarily complicating the description.

As the need for cloud services and big data applications increases, there is an increasing need for increased storage volume. An electronic system (e.g., a server system) can have increased storage volume by increasing the storage volume of a single storage device and/or by increasing the total number of storage devices included in the electronic system. In the server system, a backplane printed circuit board (PCB) is often affixed to a server chassis and includes a slot (or connector) to receive a server element (e.g., a storage device such as hard disk drive, “HDD”). The backplane PCB may be shortly referred to as a “backplane.” A backplane PCB that hosts one or more HDDs may be referred to as “HDD backplane.”

A controller of the electronic system may be configured to monitor state(s) of one or more electronic elements of the electronic system. For example, a controller (e.g., a host bus adapter, “HBA”) of the server system (e.g., a server) may monitor state(s) of a storage device (or other server component), e.g., by communicating with a circuit board (e.g., the backplane) that hosts the storage device via a serial general purpose input/output (SGPIO) bus or a programming voltage bus (“Vpp bus”). Such controller may control to turn on, or turn off, one or more status indicator lights (e.g., one or more LEDs on the backplane) that are associated with the storage device, to indicate one or more states of the storage device. When the one or more status indicator lights are on the backplane (or other circuit board) that provides limited space, there is a need to reduce the packaging size of a circuit (or a portion of the circuit) that includes the one or more status indicator lights (e.g., LEDs).

Systems and methods are disclosed herein that relate to reducing a packaging size of one or more electronic elements for an electronic system (or a portion thereof, such as a circuit board) that has a limited volume to accommodate different components, or for an electronic system in need for a reduced volume. The electronic system can be, or can include, any applicable electronic device. For example, in various embodiments, the electronic system can be, or can include, a server having one or more storage devices. A storage device may be connected to a backplane that has a considerably less space than a motherboard to accommodate electronic component(s). In various embodiments, a three-dimensional packaging structure is applied that packages one or more electronic elements (e.g., circuit elements such as transistor, resistor, etc.) of an electronic system or a portion thereof (e.g., a circuit for driving one or more LEDs that indicate a status of a hardware component such as a storage device).

The three-dimensional packaging structure may be a multi-layer structure with each layer corresponding to an electronic element (e.g., circuit element). Such multi-layer structure enables the backplane (or other circuit board or an electronic system) to have more spare space to include or host slots (or connectors) that receive or connect electronic components such as hard disk drive (HDD), solid-state drives (SSD), complex programmable logic device (CPLD), etc. The inclusion of additional storage devices (e.g., HDDs, SSDs) may, for a server system, increase the storage volume of the server system without the need to include additional backplanes or circuit boards. While various embodiments of the electronic system are described using examples of a server system or a server, the disclosed multi-layer 3D packaging structure or associated methods/systems may be applicable to any other electronic systems.

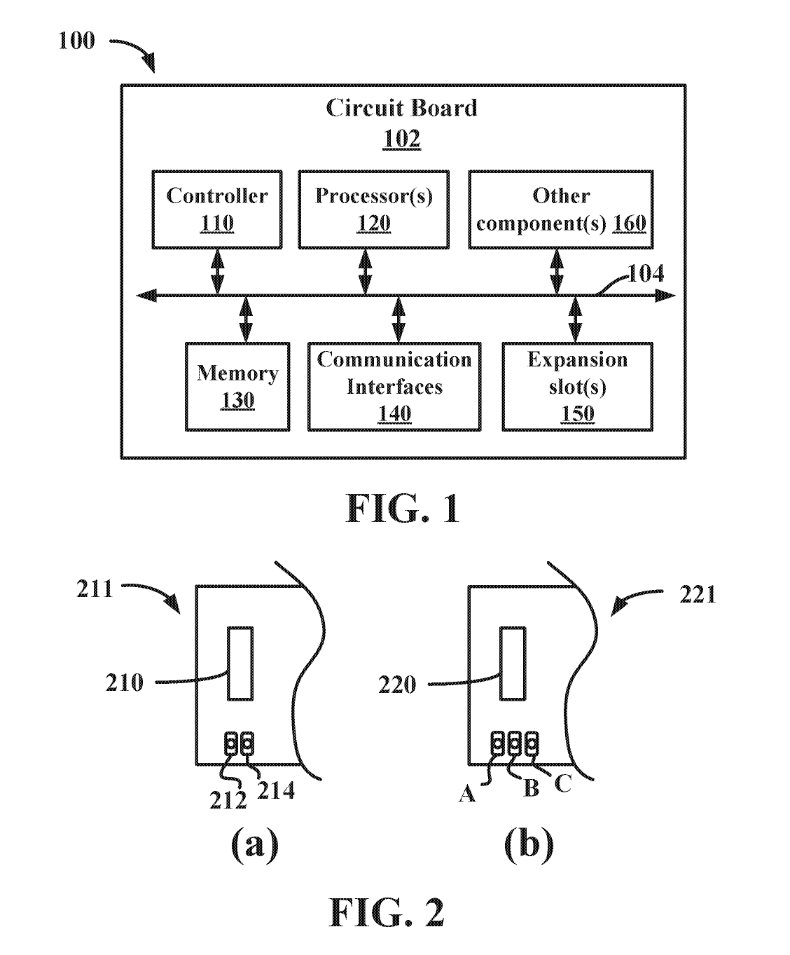

FIG. 1 illustrates a block diagram of a system 100, e.g., server, suitable for use in implementing embodiments of the present disclosure. It should be noted that the arrangements described herein, including this example, are provided for illustrative purposes only. Alternative configurations and components may be used in place of or in addition to those shown, and some components may be omitted entirely. Moreover, many of the elements described are functional in nature and can be implemented as standalone or distributed components or devices, either independently or in combination with other components, and located in various configurations. The functions discussed may be executed through hardware, firmware, and/or software, with processes typically performed by a processor running instructions stored in memory. Additionally, those skilled in the art will recognize that any system capable of performing the operations of the server system 100 falls within the scope and intent of the disclosed embodiments. The server system 100 can be housed in a rack-mounted chassis designed for optimal airflow and cooling, ensuring efficient heat dissipation during operation. Yet further, a person skilled in the art will recognize that the systems and methods described herein can be used with electronic systems and computer systems other than server systems.

The system 100 typically includes at least one circuit board 102, e.g., a motherboard, that may carry various components, including hardware, firmware, and/or software, which may be integrated with, attached to, connected to, or in communication with the motherboard. As shown in FIG. 1, the circuit board 102 carries at least one controller 110, such as a baseboard management controller (BMC), one or more processors 120, memory 130, communication interfaces 140, one or more expansion slots 150, and one or more other components 160. Such components and the circuit board 102 can communicate with one another through a bus 104, which may be integrated into the circuit board 102.

Processor(s) 120 may be configured to perform the operations in accordance with the computer readable instructions stored in memory 130. In certain embodiments, the memory 130 may be integral to the processor(s) 120. In other embodiments, the memory may in whole or in part be separate from the processor(s) 120. Processor(s) 120 may include any appropriate type of general-purpose or special-purpose microprocessor or microcontroller (e.g., a central processing unit (CPU) or graphics processing unit (GPU), respectively), digital signal processor, microcontroller, or the like. Memory 130 may be configured to store computer-readable instructions that, when executed by processor(s) 120, can cause processor(s) 120 to perform various operations disclosed herein and/or store data relating thereto.

Memory 130 may be any non-transitory type of mass storage, such as volatile or non-volatile, magnetic, semiconductor-based, tape-based, optical, removable, non-removable, or other type of storage device or tangible computer-readable medium including, but not limited to, a read-only memory (“ROM”), an electrical erasable programmable ROM (EEPROM), a flash memory, a dynamic random-access memory (“RAM”), and/or a static RAM. In certain embodiments, memory 130 may include multiple storage devices of various types.

Communication interfaces 140 may be configured to communicate information between system 100 and other devices or systems. For example, communication interfaces 140 may include an integrated services digital network (“ISDN”) card, a cable modem, a satellite modem, or a modem to provide a data communication connection. As another example, communication interfaces 140 may include a local area network (“LAN”) card to provide a data communication connection to a compatible LAN. As a further example, communication interfaces 140 may include a high-speed network adapter such as a fiber optic network adaptor, 10G Ethernet adaptor, or the like. Wireless links can also be implemented by communication interfaces 140. In such an implementation, communication interfaces 140 can send and receive electrical, electromagnetic, or optical signals that carry digital data streams representing various types of information via a network. The network can typically include a cellular communication network, a Wireless Local Area Network (“WLAN”), a Wide Area Network (“WAN”), or the like.

Controller 110, e.g., BMC, may include a processing unit, associated memory, and communication interfaces, and is configured to monitor and manage the system’s hardware components among other things. Controller 110 handles tasks such as remote system management, including hardware health monitoring, system event logging, and power control. Controller 110 can operate independently of the system’s 100 main processor (e.g., processor(s) 120), allowing for out-of-band management. Controller 110 may in certain embodiments facilitate communication with various sensors (e.g., other component(s) 160) on the circuit board 102 to track temperature, fan speed, voltage levels, and other critical parameters. Additionally, the controller 110 may include network interfaces and/or operate in conjunction with communication interfaces 140 to enable remote access for system administrators, providing a way to perform diagnostic tasks, power cycling, and firmware updates.

The expansion slot(s) 150 on the circuit board 102 may be used for connecting additional peripherals, such as GPUs, network cards, and more.

The other components 160 can include integrated components, replaceable components, and other suitable components. For example, these components may include but are not limited to sensors, cooling devices, power supply modules (and/or connectors), clock generators, chipsets, and more. In one or more embodiments, a chipset refers to a component or a group of components that manage communication between the CPU, memory (RAM), storage devices, network interfaces, and other peripherals.

FIG. 2 illustrates two block diagrams each showing a section of a backplane that includes one or more status indicators. Referring to scenario (a) in FIG. 2, a section of a first backplane 211 includes a connector 210 (e.g., to host/connect a storage device such as HDD) and two light-emitting diodes (LEDs) to indicate status of the connector 210 (or of the storage device). The status of the connector 210 may be represented using one of a plurality of states, such as “on,” “off,” “blinking,” etc.

For instance, given the example above, the two LEDs include a first LED 212 (e.g., an activity LED) and a second LED 214 (e.g., a status LED). The first LED 212 may be “off,” indicating that no storage device is present (e.g., no storage device connected to the connector 210). The first LED 212 may be “on,” indicating that a storage device is present but performs no activity (“present but not active”). The first LED 212 may be “blinking” (e.g., blinks at a first frequency, such as 4Hz, etc.), to indicate that a storage device is connected to the connector 210 and is active. Or, the first LED 212 may be “blinking” at the first frequency (or a second frequency) to indicate that the host controller is attempting to locate (or identify) the storage device. The second LED 214 may emit a second color (e.g., orange or yellow) while a first color (e.g., green) is emitted by the first LED 212. The second LED 214 may be “On” to indicate a fault of the storage device, may be blinking at a first pattern (or at a first predefined frequency, e.g., 4Hz) to indicate that locating of the storage device is being performed, or may be blinking at a second pattern (or a second predefined frequency, e.g., 1Hz) to indicate that a drive for the storage device is being rebuilt.

Referring to scenario (b) in FIG. 1, a section of a second backplane 221 includes a connector 220 (e.g., to host a storage device such as HDD) and three light-emitting diodes (LEDs) associated with the connector 220 (or the storage device). The three LEDs include LED A (e.g., an activity LED), a LED B (e.g., a failure LED), and LED C (e.g., a location LED). LED A may be “off,” indicating that no storage device is present (e.g., no storage device connected to the connector 220). LED A may be “on,” indicating that a storage device is present but performs no activity (“present but not active”). LED A may be “blinking” (e.g., blinks at the first frequency, such as 4Hz, etc.), to indicate that a storage device is connected to the connector 120 and is active. LED B may be “On” to indicate a fault of the storage device, may be blinking at the first pattern (or a different pattern or a frequency) to indicate a predicted failure, or may be blinking at the second pattern (or a different pattern or a frequency) to indicate that a drive for the storage device is being rebuilt. LED C may be blinking (e.g., at a frequency of 4Hz) to indicate a state of “locating.” It’s noted that, a circuit board (e.g., a motherboard, a backplane, etc.) may include less than 2 LEDs associated with a slot (or connector, or an electronic component/element), or include more than 3 LEDs associated with the slot (or connector, or electronic component/element). The present disclosure is not intended to be limiting.

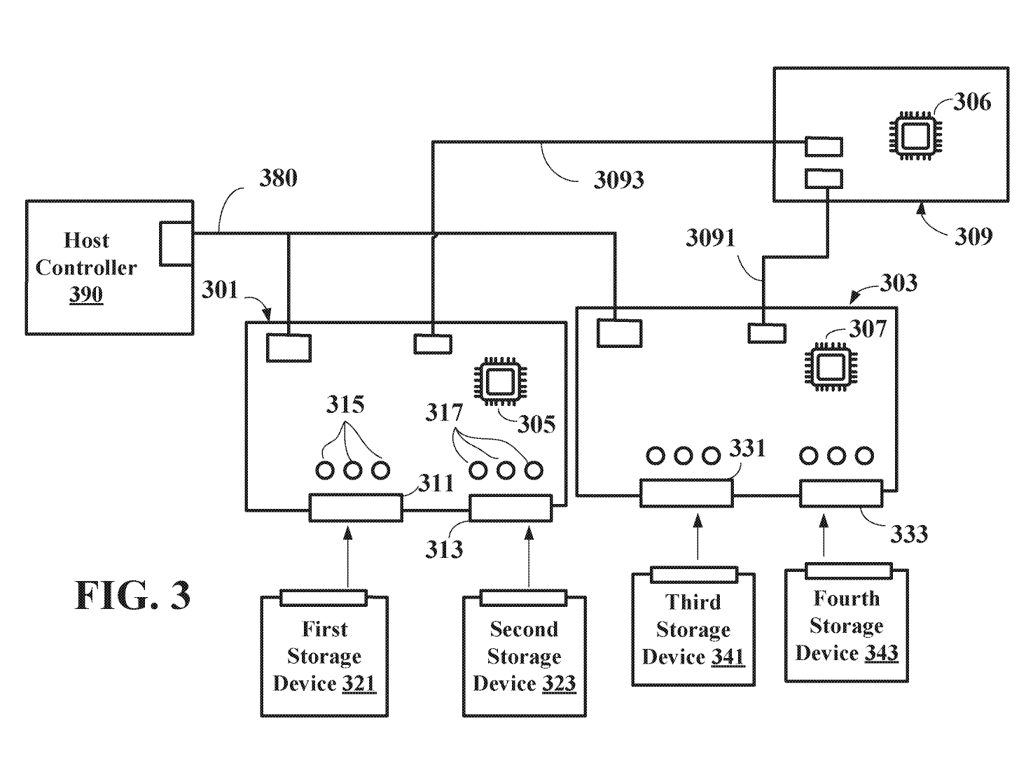

FIG. 3 illustrates a block diagram of an electronic system including one or more circuit boards. The one or more circuit boards can include, for instance, a first backplane 301 and a second backplane 303. The first backplane 301 and the second backplane 303 can be included in a server device, and can be connected (e.g., electrically and physically connected) to a host controller 390 (e.g., a host bus adapter, “HBA”). The first backplane 301 (or the second backplane 303) can be a HDD backplane that includes one or more slots to receive one or more storage devices (e.g., HDDs). For example, the first backplane 301 may include a first slot 311 for connection to a first storage device 321 (e.g., first HDD) via, for instance, a SAS or SATA cable. In this example, the first backplane 301 may further include a second slot 313 for connection to a second storage device 323 (e.g., second HDD) via, for instance, a SAS or SATA cable. The first backplane 301 may include a first backplane controller 305. The first backplane controller 305 can be, for instance, a target controller.

The second backplane 303 may include a first slot 331 for connection to a third storage device 341 (e.g., a HDD), and a second slot 333 for connection to a fourth storage device 343 (e.g., a HDD). The second backplane 303 may include a second backplane controller 307. The second backplane controller 307 can be, for instance, a target controller. The host controller 390 may include a connector for connection (e.g., electrically) to a communication link 380, e.g., a serial general-purpose input/output (SGPIO) bus (also referred to as “4x iPass cable”) that carries SGPIO signal(s). The 4x iPass cable may be split for connection to the first backplane 301 and the second backplane 303. The first backplane 301 may be connected (e.g., electrically) to a motherboard 309, e.g., via a first communication link 3091 (e.g., an Inter-Integrated Circuit “I2C” bus, or a System Management Bus “SMBus”). The second backplane 303 may be connected (e.g., electrically) to the motherboard 309, e.g., via a second communication link 3093 (e.g., I2C bus, or SMBus). The motherboard 309 may include, for instance, a controller 306.

The first backplane 301 (or the second backplane 303) may, via a SGPIO interface, acquire SPIO stream(s), for the target controller 305 (or 307) to provide control signals to status indicators (e.g., a first group of LEDs 315 and/or a second group of LEDs 317). The first group of LEDs 315 may indicate one or more states of the first slot 311 of the first backplane 301 and/or may indicate one or more states of the first storage device 321. The second group of LEDs 317 may indicate one or more states of the second slot 313 of the first backplane 301 and/or may indicate one or more states of the second storage device 323. The first group of LEDs 315 (or the second group of LEDs 317) may include, for instance, the activity indicator (e.g., “LED A” in FIG. 1b), the failure indicator (e.g., “LED B” in FIG. 1b), location indicator (e.g., “LED C” in FIG. 1b), rebuild indicator (if applicable), and/or any other applicable indicator, or any combination thereof. Similar descriptions for the second backplane 303 are omitted for the sake of brevity.

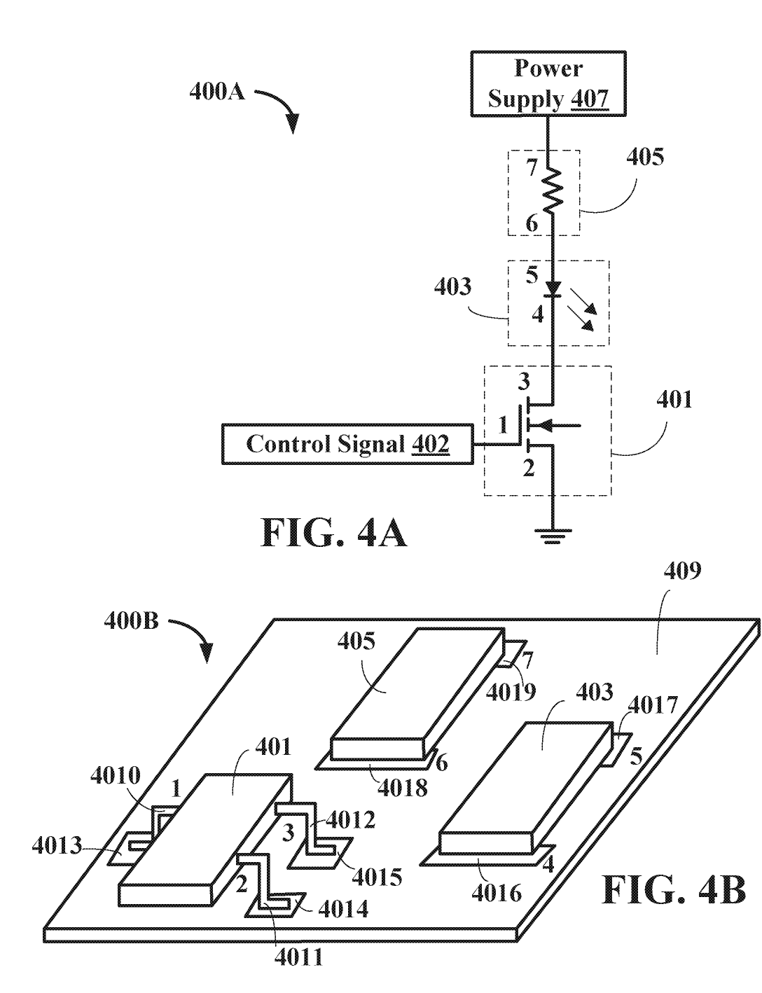

FIG. 4A illustrates a schematic diagram of an example of a portion of a circuit 400A, according to one or more embodiments of the present disclosure. As shown in FIG. 4A, the circuit 400A may include a transistor 401, a light-emitting element 403 (e.g., a light-emitting diode, “LED”), and/or a resistor 405. The transistor 401 may be a field effect transistor (FET) such as a metal oxide semiconductor field effect transistor (MOSFET, e.g., n-channel MOSFET), other types of transistor, or other types of switching unit. The transistor 401 may include a first terminal/region (e.g., “gate terminal,’ shortly as “gate,” designated by “point 1”) to receive a control signal 402 for turning on the light-emitting element 403, turning off the light-emitting element 403, or configuring the light-emitting element 403 (e.g., to blink at a certain pattern or at a predefined frequency). The transistor 401 may include a second terminal/region (e.g., “source terminal,” shortly as “source,” see “point 2”) that is connected to the ground, and a third terminal/region (e.g., “drain terminal,” shortly as “drain,” see “point 3” in FIG. 4A). The drain region/terminal (“point 3”) may be connected (e.g., electrically) to a first end (“point 4”) of the light-emitting element 403, and a second end (“point 5”) of the light-emitting element 403 may be connected to a first end (“point 6”) of the resistor 405. A second end (“point 7”) of the resistor 405 may be configured to receive a power supply 407.

In some embodiments, alternatively, the drain region (“point 3” in FIG. 4A) of the transistor 401 may be connected (e.g., electrically) to the first end (“point 6” in FIG. 4A) of the resistor 405, and the second end (“point 7” in FIG. 4A) of the resistor 405 may be connected (e.g., electrically) to the first end (“point 4”) of the light-emitting element 403. The second end (“point 5” in FIG. 4A) of the light-emitting element 403 may be configured to receive the power supply 407. The present disclosure is not intended to be limiting.

FIG. 4B illustrates an example packaging structure 400B for the portion of the circuit in FIG. 4A, according to one or more embodiments of the present disclosure. As shown in FIG. 4B, the transistor 401 may be disposed on a first surface of a substrate 409 (e.g., a circuit board like a printed circuit board, “PCB”). The light-emitting element 403 may be disposed on the first surface of the circuit board 409, and the resistor 405 may be disposed on the first surface of the board 409. In some embodiments, the transistor 401 may be a surface-mount device (“SMD”) transistor, such as a SMD metal oxide semiconductor field effect transistor (MOSFET). In some embodiments, the light-emitting element 403 may be a SMD LED. In some embodiments, the resistor 405 may be a SMD resistor. By using circuit elements such as SMD transistor, SMD LED, and/or SMD resistor in some embodiments of the present disclosure, it is easier and more convenient to replace or remove one or more of the circuit elements as these circuit elements, when packaged as SMD, include one or more conductive regions (or conductive components such as two pins, four pins, six pins) for electrical connection, and therefore are not equipped with lead(s) that extend through holes (e.g., through-holes, etc.) of the circuit board 409.

In some embodiments, referring to FIG. 4B, the gate terminal “1” of the transistor 401 may be in contact with the circuit board 409 via a first connecting pin (“first pin”) 4010, and the first pin 4010 may be fixedly connected (e.g., soldered) to the circuit board 409 via a first pad 4013 (e.g., a solder pad made of copper or silver). The first pin 4010 and/or the first pad 4013 may enable the gate terminal “1” to receive a control signal carried by a first conductive trace (not shown) of the circuit board 409, to control whether to turn on the light-emitting element 403, to turn off the light-emitting element 403, or to configure the light-emitting element 403 to blink, etc. In some embodiments, the source region “2” of the transistor 401 may be in contact with the circuit board 409 via a second connecting pin (“second pin”) 4011, and the second pin 4011 may be fixedly connected (e.g., soldered) to the circuit board 409 via a second pad 4014 (e.g., a solder pad made of copper or silver). In some embodiments, the drain region “3” of the transistor 401 may be in contact with the circuit board 409 via a third connecting pin (“third pin”) 4012, and the third pin 4012 may be fixedly connected (e.g., soldered) to the circuit board 409 via a third pad 4015 (e.g., a solder pad made of copper or silver). The third pin 4012 and/or the third pad 4015 may enable the drain region “3” of the transistor 401 to be electrically connected to the light-emitting element 403 (sometimes, alternatively, the resistor 405) via a second conductive trace (not shown).

In some embodiments, the first end “4” of the light-emitting element 403 may be fixedly connected (e.g., soldered) to the circuit board 409 via a fourth pad 4016 (e.g., a solder pad made of copper or silver). The second end “5” of the light-emitting element 403 may be fixedly connected (e.g., soldered) to the circuit board 409 via a fifth pad 4017 (e.g., a solder pad made of copper or silver). In some embodiments, the first end “6” of the resistor 405 may be fixedly connected (e.g., soldered) to the circuit board 409 via a sixth pad 4018 (e.g., a solder pad made of copper or silver). The second end “7” of the resistor 405 may be fixedly connected (e.g., soldered) to the circuit board 409 via a seventh pad 4019 (e.g., a solder pad made of copper or silver). The light-emitting element 403 may be electrically connected to the resistor 405 via a third conductive trace (not shown, e.g., embedded in the circuit board 409 or on top of the first surface of the circuit board 409). As a non-limiting example, the third conductive trace may connect the second end “5” of the light-emitting element 403 with the first end “6” of the resistor 405. In some embodiments, the circuit board 409 is a motherboard or a board of a relatively large size to accommodate or host other electronic components (e.g., an on-board controller, one or more connectors to connect components such as a storage device, a cable, etc.), such that the transistor 401, the light-emitting element 403, and the resistor 405 can be disposed on the top surface of the circuit board 409 and be spaced apart from each other.

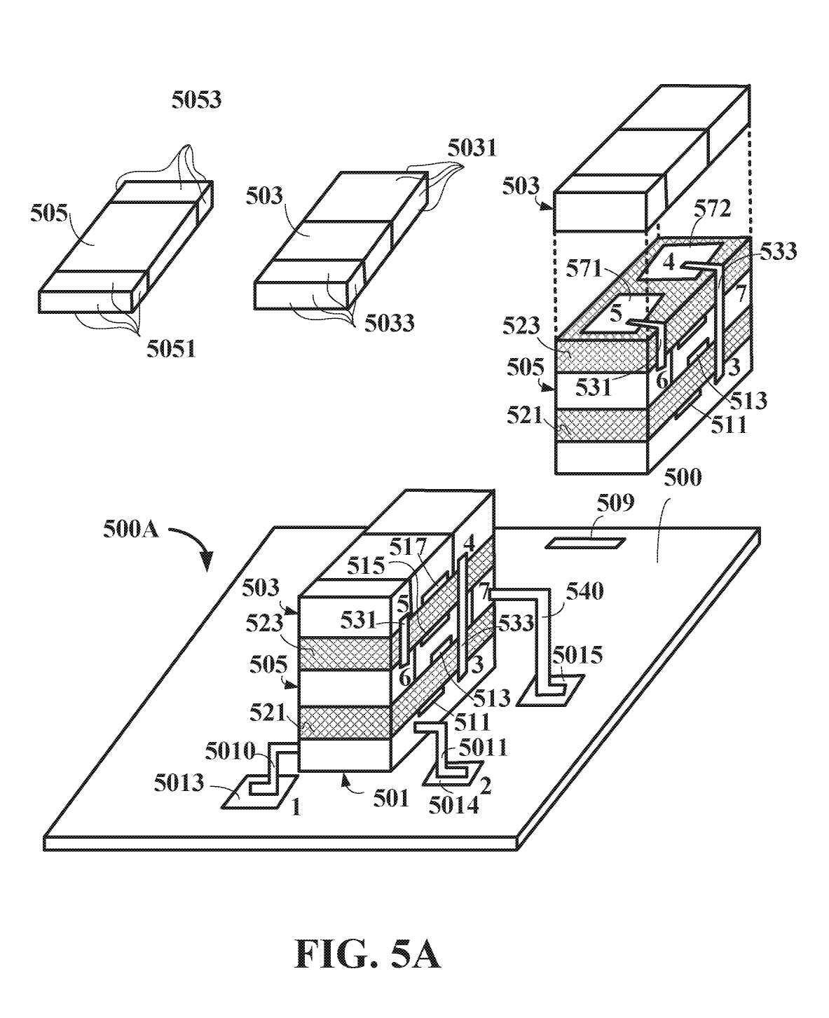

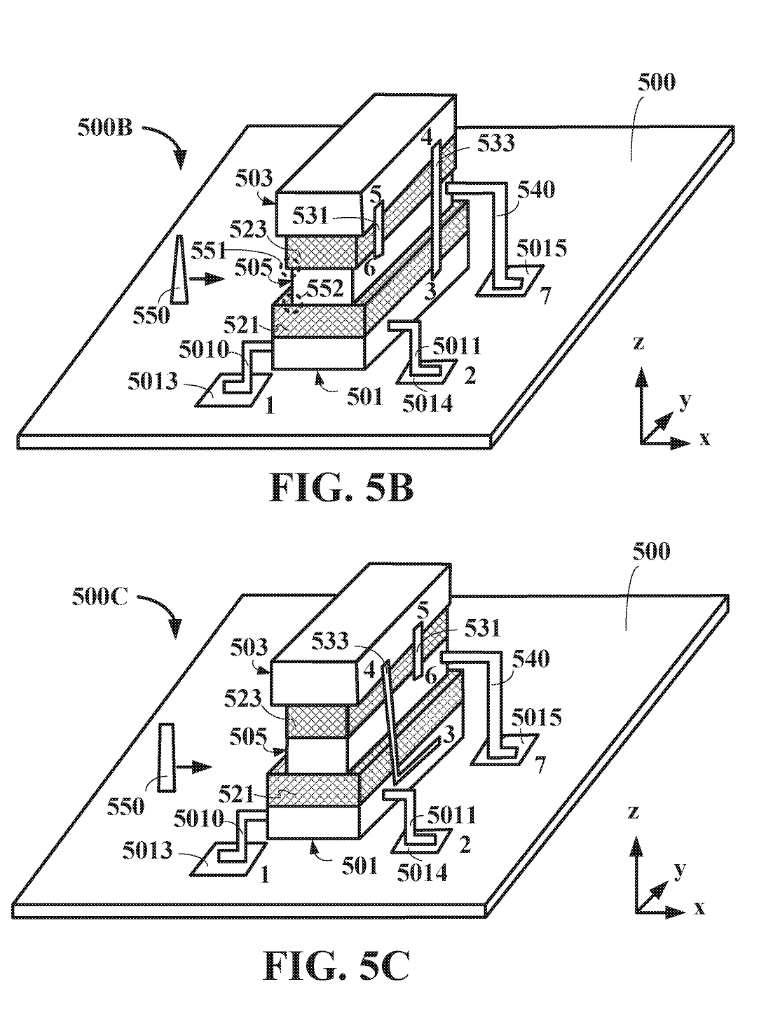

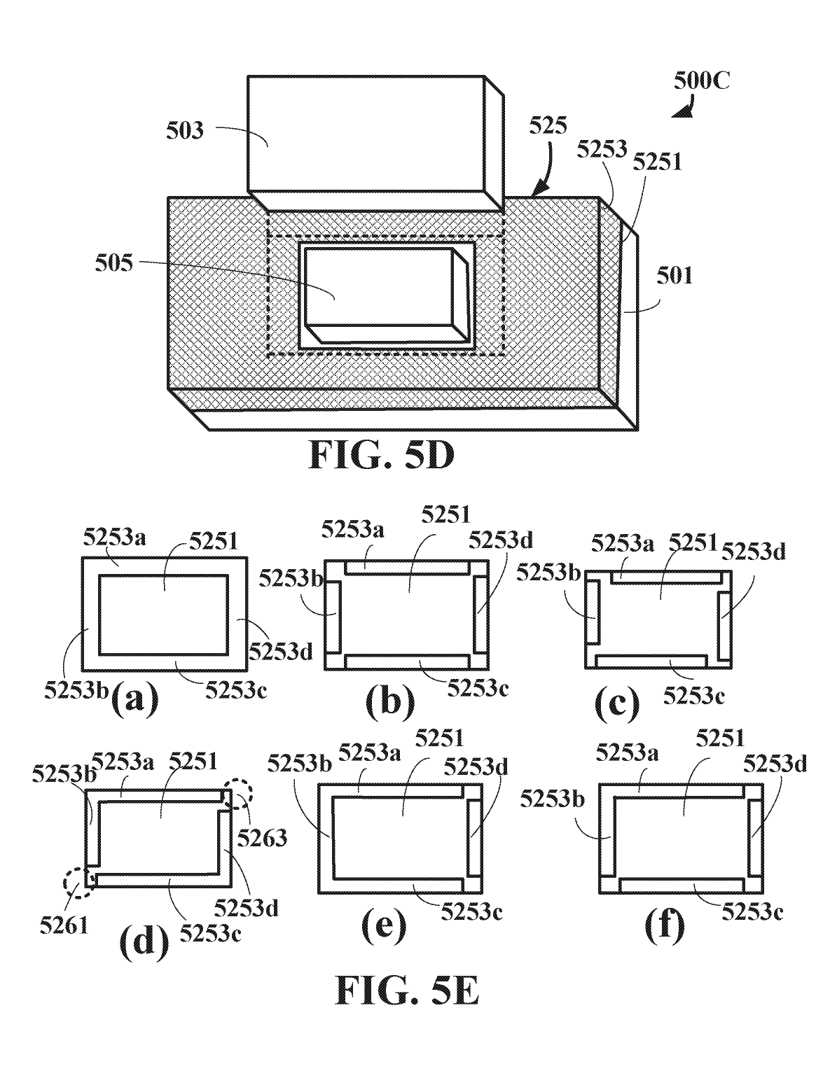

FIG. 5A illustrates another example of a packaging structure 500A for the portion of the circuit in FIG. 4A, according to one or more embodiments of the present disclosure. FIG. 5B illustrates a further example packaging structure 500B for the portion of the circuit in FIG. 4A. FIG. 5C illustrates another example packaging structure 500C for the portion of the circuit in FIG. 4A. As shown in FIG. 5A, the packaging structure 500A may be a multi-layer structure. The packaging structure 500A may include a transistor layer having a transistor 501. The transistor layer (or the transistor 501) may be disposed on a first surface of a substrate 500 (e.g., a circuit board such as a PCB). The transistor 501 may be a SMD transistor (e.g., SMD MOSFET).

In some embodiments, the gate terminal “1” of the transistor 501 may be in contact with the circuit board 500 via a first connecting pin (“first pin”) 5010, and the first pin 5010 may be fixedly connected (e.g., soldered) to the circuit board 500 via a first pad 5013 (e.g., a solder pad made of copper or silver). The first pin 5010 and/or the first pad 5013 may enable the gate terminal “1” to receive a control signal carried by a first conductive trace of the circuit board 500, to control whether to turn on the light-emitting element 503, to turn off the light-emitting element 503, or to configure the light-emitting element 503 to blink, etc. In some embodiments, the source region “2” of the transistor 501 may be in contact with the circuit board 500 via a second connecting pin (“second pin”) 5011, and the second pin 5011 may be fixedly connected (e.g., soldered) to the circuit board 500 via a second pad 5014 (e.g., a solder pad made of copper or silver).

In some embodiments, the packaging structure 500A may further include a first heat-dissipation layer 521 disposed on the transistor layer. In some embodiments, the packaging structure 500A may include a first adhering layer 511 sandwiched between the transistor layer (or the transistor 501) and the first heat-dissipation layer 521. The first adhering layer 511 may include one or more adhering regions (e.g., made of silver glue) to adhere the first heat-dissipation layer 521 onto the transistor 501, or may include a layer of adhering agent (e.g., silver glue) that adheres the first heat-dissipation layer 521 onto the transistor 501. The first heat-dissipation layer 521 may be made of an insulating material. For example, the first heat-dissipation layer 521 may be a ceramic layer including one or more ceramic materials, or may be an insulating layer made of aluminum oxide, or other suitable heat-dissipating material.

In some embodiments, the packaging structure 500A may further include a resistor layer that includes a resistor 505. The resistor layer (or the resistor 505) may be disposed on the first heat-dissipation layer 521. In some embodiments, the packaging structure 500A may further include a second adhering layer 513 sandwiched between the resistor layer (or the resistor 505) and the first heat-dissipation layer 521, to adhere the resistor layer (or the resistor 505) to the first heat-dissipation layer 521. In some embodiments, the resistor 505 may be a SMD resistor.

In some embodiments, the packaging structure 500A may further include a second heat-dissipation layer 523 disposed on the resistor layer. In some embodiments, the packaging structure 500A may include a third adhering layer 515 sandwiched between the resistor layer (or the resistor 505) and the second heat-dissipation layer 523. In some embodiments, the packaging structure 500A may further include a light-emitting layer that includes the light-emitting element 503. The light-emitting layer (or the light-emitting element 503) may be disposed on the second heat-dissipation layer 523. In some embodiments, the packaging structure 500A may further include a fourth adhering layer 517 sandwiched between the light-emitting layer (or the light-emitting element 503) and the second heat-dissipation layer 523, to adhere the light-emitting layer (or the light-emitting element 503) to the second heat-dissipation layer 523. In some embodiments, the light-emitting element 503 may be a SMD LED. In some embodiments, the SMD LED may be a single-color LED having, e.g., two conductive regions for electrical connection. In some embodiments, the SMD LED may be a dual-color LED having, e.g., four conductive regions for electrical connection.

The second adhering layer 513, the third adhering layer 515, and/or the fourth adhering layer 517 may be the same as, or similar to, the first adhering layer 511. The second heat-dissipation layer 523 may be the same as, or similar to the first heat-dissipation layer 521.

In some embodiments, referring to FIG. 5A, the resistor 505 may include a first conductive region 5051 (e.g., corresponding to, or including, the first end “6”) and a second conductive region 5053 (e.g., corresponding to, or including, the second end “7”). In some embodiments, the light-emitting element 503 may include a first conductive region 5031 (e.g., corresponding to the first end “4”) and a second conductive region 5033 (e.g., corresponding to the second end “5”). In some embodiments, the packaging structure 500A may further include a first conductive element 531 that connects the first conductive region 5051 (e.g., corresponding to the first end “6”) of the resistor 505 with the second conductive region 5033 (e.g., corresponding to the second end “5”) of the light-emitting element 503. In some embodiments, a first end of the first conductive element 531 may be fixedly connected (e.g., soldered to a first soldering region 571) to a top surface of the second heat dissipation layer 523 that faces away from the resistor 505. Additionally, or alternatively, a second end of the first conductive element 531 may be fixedly connected (e.g., soldered) to a bottom surface of the second heat dissipation layer 523 that faces the resistor 505.

In some embodiments, the packaging structure 500A may further include a second conductive element 533 that connects the drain region “3” of the transistor 501 with the first conductive region 5031 (e.g., corresponding to the first end “4”) of the light-emitting element 503. In some embodiments, a first end of the second conductive element 533 may be fixedly connected (e.g., soldered to a second soldering region 572) to the top surface of the second heat dissipation layer 523 that faces away from the resistor 505. Additionally, or alternatively, a second end of the second conductive element 533 may be fixedly connected (e.g., soldered) to the bottom surface of the first heat dissipation layer 521 that faces away the resistor 505. In some embodiments, the first soldering region 571 is disposed on the top surface of the second heat-dissipation layer 523 and includes a conductive pad made of a conductive material (e.g., silver, copper, etc.). In some embodiments, the second soldering region 572 is disposed on the top surface of the second heat-dissipation layer 523 and includes a conductive pad made of a conductive material (e.g., silver, copper, etc.).

In some embodiments, the resistor 505 may include a conductive connector 540 (a conductive pin or a conductive strip having a predefined width, etc.). In some embodiments, the conductive connector 540 may include a first end and/or a second end. The first end of the conductive connector 540 may be connected to the second conductive region 5053 (e.g., corresponding to the second end “7”) of the resistor 505, and the second end of the conductive connector 540 may be fixedly connected to the circuit board 500 (e.g., soldered to the circuit board 500 via a third pad 5015) for further connection to a power supply unit (not illustrated). Or, the second end of the conductive connector 540 may be directly connected to the power supply unit. In some embodiments, the circuit board 500 is a motherboard. In some embodiments, the circuit board 500 is a backplane including a connector 509 to connect a storage device (e.g., HDD). Descriptions of the circuit board 500 is not limited thereto, and can be any applicable board.

In some embodiments, referring to FIG. 5B, the transistor 501, the light-emitting element 503, and the resistor 505, of a packaging structure 500B, may have different shapes and/or sizes with respect to each other. For example, an area (e.g., projection area), of a surface of the resistor 505, that is parallel to the circuit board 500 may be smaller than an area, of a surface of the light-emitting element 503, that is parallel to the circuit board 500. Additionally, or alternatively, the area, of the surface of the resistor 505, parallel to the circuit board 500 may be smaller than an area (e.g., projection area), of a surface of the transistor 501, that is parallel to the circuit board 500. In this case, the packaging structure 500B may further include one or more supporting structures/elements 550 sandwiched between the first heat-dissipation layer 521 and the light-emitting element 503 (or the second heat-dissipation layer 523), to support the light-emitting element 503 (or to support the second heat-dissipation layer 523). The one or more supporting elements/structures 550 may include, for example, a plurality of support columns disposed around (e.g., in proximity to) the resistor 505.

In some embodiments, an area of a first surface of the second heat-dissipation layer 523 facing the resistor 505 is greater than or equal to an area of a top surface of the resistor 505 that faces the second heat-dissipation layer 523. In this case, the one or more supporting structures 550 may be disposed along a periphery of the first surface of the second heat-dissipation layer 523 that faces the first heat-dissipation layer 521. For example, the one or more supporting structures 550 (also referred to as “supporting element,” “support structure,” or “support element”) may include four support structures (e.g., having a shape of cylinder, tapered columns, or any other applicable shape), with each support structure being disposed to support a corresponding corner 551 of the second heat-dissipation layer 523.

In some embodiments, as seen in FIG. 5C, an area of the first heat-dissipation layer 521 is greater than an area of the second heat-dissipation layer 523. In some embodiments, an area of the first heat-dissipation layer 521 is less than, or equal to, an area of the second heat-dissipation layer 523. For example, an area of the second heat-dissipation layer 523 may be greater than or equal to an area of the first heat-dissipation layer 521, and the area of the layer having the resistor 505 may be greater than an area of the first heat-dissipation layer 521. In this case, the one or more supporting structures 550 may be disposed between the first and second heat-dissipation layers. For example, the one or more supporting structures 550 may be disposed along a periphery of a surface of the first heat-dissipation layer 521 that faces the second heat-dissipation layer 523. For example, the one or more supporting structures 550 may include four support structures (e.g., having a shape of cylinder, tapered columns, or any other applicable shape), with each support structure being disposed at a corresponding corner 552 of the first heat-dissipation layer 521 (or at any other applicable location, such as a mid-point of a corresponding side of the area of the first heat-dissipation layer 523 along the first direction).

In some embodiments, referring to FIG. 5B and FIG. 5C, the first conductive element 531 connecting the second end (denoted by point “5” in a circuit, e.g., in FIG. 4A) of the light-emitting element 503 and the first end (denoted by point “6”) of the resistor 505 may have a different shape (e.g., a different width, length, and/or thickness, etc.) and/or location, if the light-emitting element 503 (and/or the resistor 505) is disposed differently (e.g., switching the first end and second end). Accordingly, the shape and/or location of the first conductive element 531 may depend on location(s) and/or size(s) of conductive region(s) of the light-emitting element 503 and/or depend on location(s) and/or size(s) of conductive region(s) of the resistor 505. The second conductive element 533 connecting the first end (denoted by point “4” in the circuit 400A in FIG. 4A) of the light-emitting element 503 and an end (i.e., “drain,” denoted by point “3”) of the transistor 501 may have a different shape (e.g., a different width, length, and/or thickness, etc.) and/or location, if the light-emitting element 503 is disposed differently. Accordingly, the shape and/or location of the second conductive element 533 may depend on location(s) and/or size(s) of conductive region(s) of the light-emitting element 503 and/or depend on location(s) and/or size(s) of conductive region(s) of the transistor 501.

In some embodiments, referring to FIG. 5D, a top view of another non-limiting example of a packaging structure 500C is provided. As shown in FIG. 5D, the packaging structure 500C may include the transistor 501 as described in FIG. 5A or FIG. 5B. In some embodiments, the packaging structure 500C may further include a heat-dissipation groove 525 disposed above the transistor 501. The heat-dissipation groove 525 may be configured to accommodate the resistor 505. The heat-dissipation groove 525 may be made of one or more insulating materials. For example, the heat-dissipation groove 525 may be made of one or more ceramics. Additionally, or alternatively, the heat-dissipation groove 525 may be made of one or more aluminum-based insulating materials (e.g., aluminum oxide). In some embodiments, the heat-dissipation groove 525 may have a porous structure to facilitate heat dissipation.

In some embodiments, referring to FIG. 5E, the heat-dissipation groove 525 may include a bottom portion 5251 and a side wall portion 5253. In some embodiments, the side wall portion 5253 may be integrated with the bottom portion 5251, or the side wall portion 5253 may be attached to the bottom portion 5251. For example, the side wall portion 5253 may be deposited on the bottom portion 5251, e.g., via 3D printing. In some embodiments, the bottom portion 5251 and the side wall portion 5253 may be made of the same insulating material, or made of different insulating materials. For example, the side wall portion 5253 may be made of a first insulating material, and the bottom portion 5251 may be made of a second insulating material that is different from the first insulating material. The side wall portion 5253 may include one or more side walls that are substantially perpendicular to the bottom portion 5251. For example, as seen in example (a) in FIG. 5D, the side wall portion 5253 may include a first side wall 5253a, a second side wall 5253b connected to the first side wall 5253a, a third side wall 5253c connected to the second side wall 5253b, and a fourth side wall 5253d that is connected to the first side wall 5253a and the third side wall 5253c, respectively. It is noted that a small deviation (e.g., ±15%) from the perpendicular direction is included in the term “substantially perpendicular.”

In some embodiments, as seen in example (b) or (c) of FIG. 5E, the first side wall 5253a, the second side wall 5253b, the third side wall 5253c, and the fourth side wall 5253d may be spaced apart from each other. In this way, heat dissipation is further enhanced. In some embodiments, as seen in example (d) of FIG. 5E, the first side wall 5253a may be connected to the second side wall 5253b, and the third side wall 5253c may be connected to the fourth side wall 5253d. In this example, the second side wall 5253b may or may not be connected to the third side wall 5253c. The fourth side wall 5253d may or may not be connected to the first side wall 5253a. For example, there may be a first opening 5261 (or a notch) between the second side wall 5253b and the third side wall 5253c. Additionally, or alternatively, there may be a second opening 5263 (or a notch) between the fourth side wall 5253d and the first side wall 5253a. The first opening 5261 (or the second opening 5263) may be configured to facilitate heat dissipation and/or to allow a conductive element connecting the resistor 505 to other circuit element or other electronic element (e.g., the circuit board 500, the light-emitting element 503, etc.).

In some embodiments, as seen in example (e) of FIG. 5E, the first side wall 5253a may be connected to the second side wall 5253b and the third side wall 5253c, respectively, and the fourth side wall 5253d is not connected to other side walls (e.g., 5253a or 5253c). In some embodiments, as seen in example (f) of FIG. 5E, the first side wall 5253a may be connected to the second side wall 5253b. In this example, the third side wall 5253c is not connected to its adjacent side wall (e.g., 5253b and 5253d), and the fourth side wall 5253d is not connected to its side walls (e.g., 5253a and 5253c). It is noted that, the structure of the heat-dissipation groove 525 is not limited to descriptions herein, and can be any applicable structure.

In some embodiments, referring again to FIG. 5C, the packaging structure 500C may further include the light-emitting element 503. In some embodiments, a height of the heat-dissipation groove 525 may be greater than a thickness of the resistor 505 accommodated in the heat-dissipation groove 525, and a bottom surface S1 of the light-emitting element 503 is greater than a top surface S2 of the resistor 505. In some embodiments, the light-emitting element 503 may be disposed on the heat-dissipation groove 525. Because the height of the heat-dissipation groove 525 is greater than the thickness of the resistor 505, the light-emitting element 503 is not in contact with the resistor 505. In some embodiments, the heat-dissipation groove 525 may further accommodate a conductive element that electrically connects point “6” of the resistor 505 and point “5” of the light-emitting element 503.

In some embodiments, the packaging structure 500C may further include a heat-dissipation layer disposed/sandwiched between the resistor 505 and the light-emitting element 503. In some embodiments, the heat-dissipation layer between the resistor 505 and the light-emitting element 503 may include an opening for a conductive element (e.g., a conductive wire) to pass through and to electrically connect the resistor 505 with the light-emitting element 503 (e.g., connect point “6” of the resistor 505 with point “5” of the light-emitting element 503).

In some embodiments, the packaging structure 500C (or 500A, 500B, etc.) may be electrically connected to an additional packaging structure (not illustrated) having an additional light-emitting element (the same as or different from the light-emitting element 503). The additional packaging structure, for instance, can include an additional resistor (the same as, similar to, or different from the resistor 505) disposed on the circuit board (e.g., 500), an additional light-emitting element (the same as or different from the light-emitting element 503), and/or a heat-dissipation layer (the same as or similar to the second heat-dissipation layer 523) sandwiched between the additional resistor and the additional light-emitting element. In this way, more than one light-emitting element may be included in the circuit (e.g., 400A) to provide multiple status indicators (e.g., the aforementioned “activity LED,” “failure LED,” and/or “Location LED”, etc.) for an electronic component (e.g., a storage device like HDD, etc.) connected to the connector 509 of the circuit board (e.g., 500).

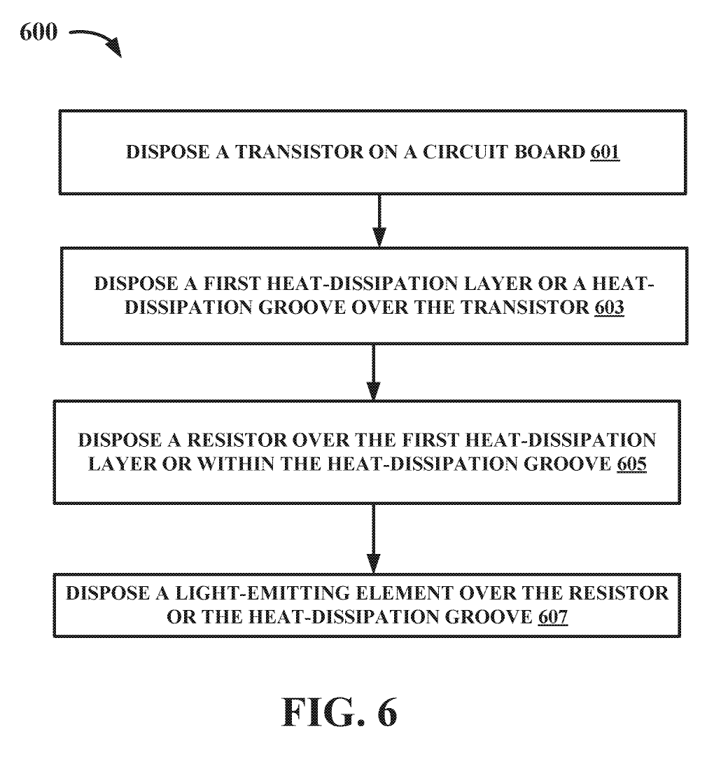

FIG. 6 illustrates a method for packaging one or more electronic elements, according to one or more embodiments of the present disclosure. While operations of the method 600 are shown in a particular order, this is not meant to be limiting. One or more operations may be reordered, omitted, and/or added except where otherwise apparent.

In various embodiments, as shown in FIG. 6, the method 600 includes, at stage 601, disposing a transistor (e.g., “501” in FIG. 5A~5D) on a circuit board or other substrate. In some embodiments, the circuit board may be a printed circuit board. In some embodiments, the PCB is a motherboard. In some embodiments, the PCB is a backplane having one or more connectors to connect with one or more electronic elements (e.g., a storage device such as HDD, SSD, etc.). The PCB may also be any other applicable board. In some embodiments, the transistor is a SMT transistor.

In various embodiments, the method 600 further includes, at stage 603, disposing a first heat-dissipation layer (e.g., “521” in FIG. 5A~5C) or a heat-dissipation groove (e.g., “525” in FIGS. 5D or 5E) over the transistor. In some embodiments, the first heat-dissipation layer includes an insulating material (e.g., aluminum oxide).

In various embodiments, the method 600 further includes, at stage 605, disposing a resistor (e.g., “505” in FIG. 5A~5D) over the first heat-dissipation layer or within the heat-dissipation groove. In some embodiments, the resistor is a SMT resistor. In some embodiments, the stages 601 and 603 may be omitted, and in this case, at stage 605, the resistor may be disposed over a circuit board (e.g., disposed directly on a circuit board).

In various embodiments, the method 600 further includes, at stage 607, disposing a light-emitting element (e.g., “503” in FIG. 5A~5D) over the resistor or the heat-dissipation groove. In various embodiments, the light-emitting element is separated from the resistor using a second heat-dissipation layer or the heat-dissipation groove. In some embodiments, the light-emitting element is a SMT LED.

In various embodiments, the method 600 further includes, prior to disposing the light-emitting element: configuring a first end of a first conductive element (e.g., “531” in FIG. 5A~5C) to connect with the resistor, and configuring a second end of the first conductive element to be connected to a first soldering region disposed on a surface of the second heat-dissipation layer that faces away from the resistor. Additionally or alternatively, in various embodiments, the method 600 further includes, prior to disposing the light-emitting element: configuring a first end of a second conductive element (e.g., “533” in FIG. 5A~5C) to connect with the transistor, and configuring a second end of the second conductive element to be connected to a second soldering region disposed on the surface of the second heat-dissipation layer that faces away from the resistor. The second soldering region is separate from the first soldering region.

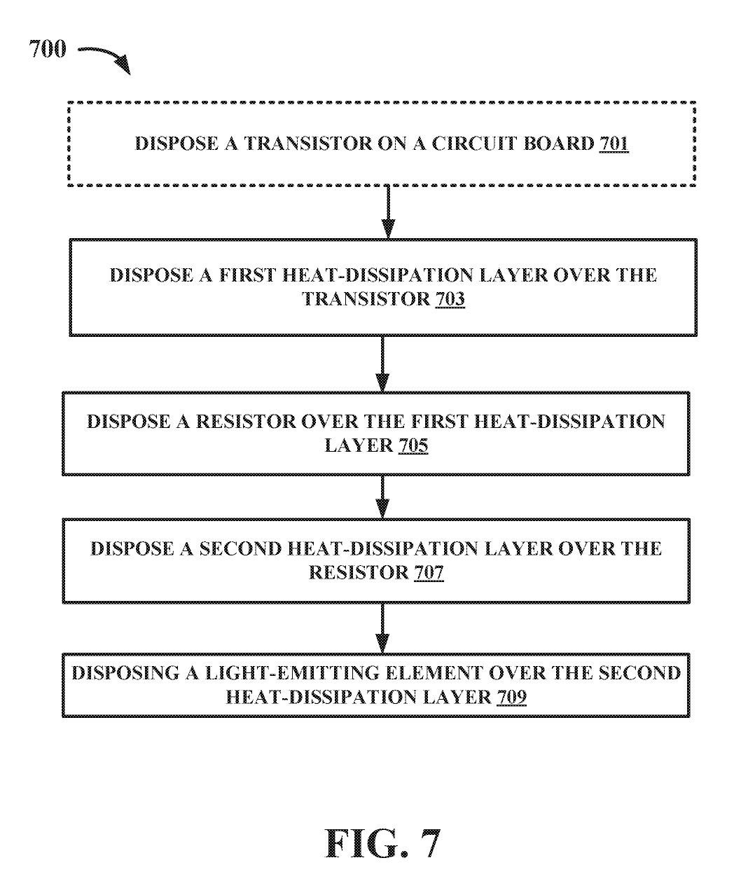

FIG. 7 illustrates another method for packaging one or more electronic elements, according to one or more embodiments of the present disclosure. While operations of the method 700 are shown in a particular order, this is not meant to be limiting. One or more operations may be reordered, omitted, and/or added.

In various embodiments, as shown in FIG. 7, the method 700 includes, at stage 701, disposing a transistor (e.g., “501” in FIG. 5A~5C) on a circuit board. In some embodiments, for example, the stage 701 may be omitted.

In various embodiments, the method 700 further includes, at stage 703, disposing a first heat-dissipation layer (e.g., “521” in FIG. 5A~5C) over the transistor.

In various embodiments, the method 700 further includes, at stage 705, disposing a resistor (e.g., “505” in FIG. 5A~5C) over the first heat-dissipation layer.

In various embodiments, the method 700 further includes, at stage 707, disposing a second heat-dissipation layer (e.g., “523” in FIG. 5A~5C) over the resistor.

In various embodiments, the method 700 further includes, at stage 709, disposing a light-emitting element (e.g., “503” in FIG. 5A~5C) over the second heat-dissipation layer.

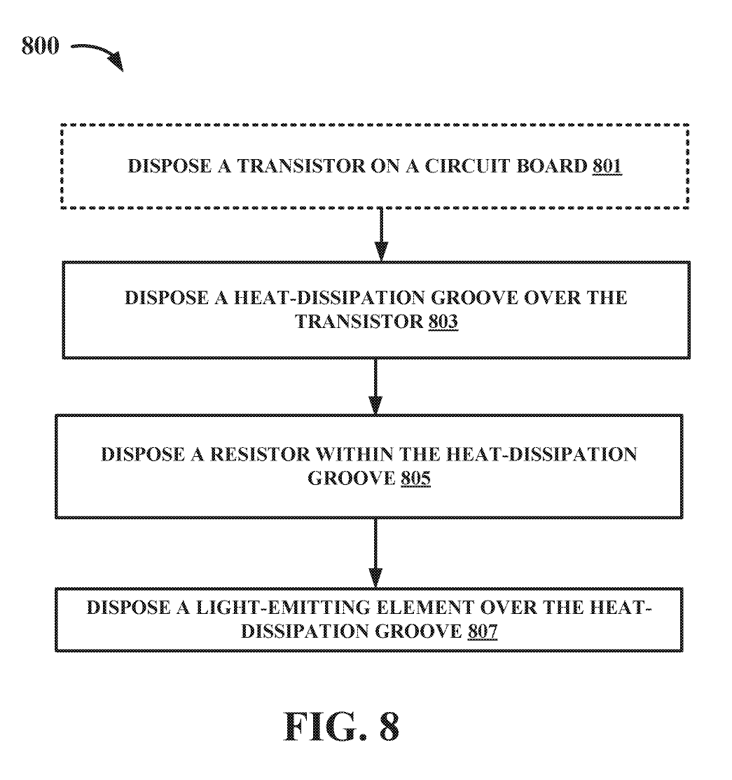

FIG. 8 illustrates a further method for packaging one or more electronic elements, according to one or more embodiments of the present disclosure. While operations of the method 600 are shown in a particular order, this is not meant to be limiting. One or more operations may be reordered, omitted, and/or added.

In various embodiments, as shown in FIG. 8, the method 800 includes, at stage 801, disposing a transistor (e.g., “501” in FIG. 5D) on a circuit board.

In various embodiments, the method 800 further includes, at stage 803, disposing a heat-dissipation groove (e.g., “525” in FIG. 5D) on the transistor.

In various embodiments, the method 800 further includes, at stage 805, disposing a resistor (e.g., “505” in FIG. 5D) within the heat-dissipation groove.

In various embodiments, the method 800 further includes, at stage 807, disposing a light-emitting element (e.g., “503” in FIG. 5D) above the heat-dissipation groove.

By using the methods (e.g., 600, 700, 800), one or more multi-layered packing structures may be provided. In some embodiments, the one or more multi-layered packaging structures may each include a light-emitting element (e.g., that emit a light to indicate a state of a corresponding HDD or any other applicable component). As a non-limiting example, the one or more multi-layered packaging structures can be connected (e.g., electrically) with each other to provide a plurality of light indicators. Due to the reduced size of area it is needed on a circuit board to accommodate the vertical configuration of a multi-layered packing structure, the total number of the multi-layered packing structures (e.g., for LED light indicator) is not limited to one or two, and can be increased or scaled up depending on a specific size, design, or dimension of the circuit board (or other structure) over which the multi-layered packing structure(s) are disposed.

In various embodiments, a packaging structure is provided. The packaging structure may include: a transistor; a resistor; a first heat-dissipation layer sandwiched between the transistor and the resistor; a light-emitting element; and/or a second heat-dissipation layer sandwiched between the first resistor and the first light-emitting element.

In some embodiments, the resistor is connected to the light-emitting element via a first conductive element. The light-emitting element can be a single-color LED or a dual-color LED for indicating a state of a component (e.g., a storage device). In some embodiments, the transistor is disposed on a circuit board. In some embodiments, the packaging structure includes a first pin connecting the transistor with the circuit board. For example, the first pin can be a conductive strip included in or coupled to the transistor, where a first end of the first pin connects a gate of the transistor and a second end of the first pin is soldered onto the circuit board to receive a control signal (e.g., via a conductive trace that transmits/carries the control signal). In some embodiments, the control signal is configured to control the light-emitting element to indicate a status (e.g., “on,” “off,” etc.) of an electronic component hosted by the circuit board. In some embodiments, the circuit board is a backplane that includes a connector for connection with the electronic component. In some other embodiments, the circuit board may be a motherboard, or any other applicable board or substrate. In some embodiments, the electronic components can be, for instance, a storage device (e.g., HDD inserted to a slot of the circuit board), or any other applicable component.

In some embodiments, the transistor includes a second pin connecting to a source of the transistor, where the second pin of the transistor is soldered onto the circuit board for connection to ground. In some embodiments, the packaging structure further includes a conductive connector that connects the resistor to the circuit board.

In some embodiments, the transistor is connected (e.g., electrically) to the light-emitting element via a second conductive element. For example, the transistor includes a drain that is connected to the light-emitting element via the second conductive element.

In some embodiments, the packaging structure further includes one or more support elements to support the second heat-dissipation layer. The one or more support elements may be sandwiched between the first and second heat-dissipation layers. In some embodiments, the one or more support elements include a plurality of tapered columns spaced apart from each other and disposed around a periphery of the first or second heat-dissipation layer.

In some embodiments, the first or second heat-dissipation layer may each include an insulating material (e.g., aluminum-based, ceramic-based, etc.). In some embodiments, the first heat-dissipation layer may include a first insulating material, and the second heat-dissipation layer may include a second insulating material. The first insulating material may be the same as, or different from, the second insulating material. In some embodiments, the first or second insulating material may each include a porous structure.

In various embodiments, a packaging structure is provided. The packaging structure includes: a transistor disposed on a substrate (e.g., a circuit board); a resistor; a heat-dissipation groove that accommodates the resistor; and a light-emitting element disposed above the heat-dissipation groove. In some embodiments, the heat-dissipation groove includes a bottom portion and a side wall portion. In some embodiments, the bottom portion of the heat-dissipation groove is sandwiched between the transistor and the resistor.

In some embodiments, the packaging structure further includes: a heat-dissipation layer disposed between the light-emitting element and the resistor (that is accommodated in the heat-dissipation groove).

In some embodiments, the side wall portion of the heat-dissipation groove includes one or more side walls substantially perpendicular to the bottom portion. In some embodiments, the side wall portion of the heat-dissipation groove includes an opening that allows a first connecting element (e.g., a conductive wire, a conductive strip, etc., see the line/connection between point “7” and “power supply 407” in FIG. 4A) to connect the resistor with the circuit board via the opening. In some embodiments, the heat-dissipation groove further accommodates a second connecting element (e.g., a conductive wire, a conductive strip, etc., see the connection between point “5” and point “6” in FIG. 4A) that connects the resistor with the light-emitting element. In some embodiments, the packaging structure further includes a third connecting element (e.g., a conductive wire, a conductive strip, etc., see the connection between point “3” and point “4” in FIG. 4A) that connects the transistor with the light-emitting element. The first, second, or third connecting element may be conductive and/or may be covered with an insulating layer (e.g., plastic, etc.)

In various embodiments, a packaging method is provided. The packaging method includes: disposing a transistor on a substrate (e.g., a circuit board); disposing a first heat-dissipation layer or a heat-dissipation groove over the transistor; disposing a resistor over the first heat-dissipation layer or within the heat-dissipation groove; and disposing a light-emitting element over the resistor or the heat-dissipation groove. In some embodiments, the light- emitting element is separated from the resistor using a second heat-dissipation layer or the heat-dissipation groove.

In some embodiments, the packaging method further includes, prior to disposing the light-emitting element: configuring a first end of a first conductive element to connect with the resistor; configuring a second end of the first conductive element to be connected to a first soldering region disposed on a surface of the second heat-dissipation layer that faces away from the resistor; configuring a first end of a second conductive element to connect with the transistor; and configuring a second end of the second conductive element to be connected to a second soldering region disposed on the surface of the second heat-dissipation layer that faces away from the resistor, the second soldering region being separate from the first soldering region.

All references, including publications, patent applications, and patents, cited herein are hereby incorporated by reference to the same extent as if each reference were individually and specifically indicated to be incorporated by reference and were set forth in its entirety herein.

The use of the terms “a” and “an” and “the” and “at least one” and similar referents in the context of describing the invention (especially in the context of the following claims) are to be construed to cover both the singular and the plural, unless otherwise indicated herein or clearly contradicted by context. The use of the term “at least one” followed by a list of one or more items (for example, “at least one of A and B”) is to be construed to mean one item selected from the listed items (A or B) or any combination of two or more of the listed items (A and B), unless otherwise indicated herein or clearly contradicted by context. The terms “comprising,” “having,” “including,” and “containing” are to be construed as open-ended terms (i.e., meaning “including, but not limited to,”) unless otherwise noted. Recitation of ranges of values herein are merely intended to serve as a shorthand method of referring individually to each separate value falling within the range, unless otherwise indicated herein, and each separate value is incorporated into the specification as if it were individually recited herein. All methods described herein can be performed in any suitable order unless otherwise indicated herein or otherwise clearly contradicted by context. The use of any and all examples, or exemplary language (e.g., “such as”) provided herein, is intended merely to better illuminate the invention and does not pose a limitation on the scope of the invention unless otherwise claimed. No language in the specification should be construed as indicating any non-claimed element as essential to the practice of the invention.

Exemplary embodiments are described herein. Variations of those exemplary embodiments may become apparent to those of ordinary skill in the art upon reading the foregoing description. It is understood that skilled artisans are able to employ such variations as appropriate, and the invention may be practiced otherwise than as specifically described herein. Accordingly, this invention includes all modifications and equivalents of the subject matter recited in the claims appended hereto as permitted by applicable law. Moreover, any combination of the above-described elements in all possible variations thereof is encompassed by the invention unless otherwise indicated herein or otherwise clearly contradicted by context.

What is claimed is:

1. A packaging structure, comprising:
a transistor;
a resistor;
a first heat-dissipation layer sandwiched between the transistor and the resistor,
a light-emitting element; and
a second heat-dissipation layer sandwiched between the resistor and the light-emitting element.

2. The packaging structure of claim 1, wherein the resistor is connected to the light-emitting element via a first conductive element.

3. The packaging structure of claim 1, wherein the transistor is disposed on a circuit board.

4. The packaging structure of claim 3, wherein the transistor comprises a first pin connecting to a gate of the transistor, the first pin of the transistor being soldered onto the circuit board to receive a control signal.

5. The packaging structure of claim 4, wherein the control signal is configured to control the light-emitting element to indicate a status of an electronic component hosted by the circuit board.

6. The packaging structure of claim 5, wherein the circuit board is a backplane comprising a connector for connection with the electronic component, and the electronic component is a storage device.

7. The packaging structure of claim 3, wherein the transistor includes a second pin connecting to a source of the transistor, the second pin of the transistor being soldered onto the circuit board for connection to ground.

8. The packaging structure of claim 3, further comprising a conductive connector that connects the resistor to the circuit board.

9. The packaging structure of claim 1, wherein the transistor includes a drain connected to the light-emitting element via a second conductive element.

10. The packaging structure of claim 1, further comprising one or more support elements to support the second heat-dissipation layer, the one or more support elements being sandwiched between the first and second heat-dissipation layers.

11. The packaging structure of claim 10, wherein the one or more support elements include a plurality of tapered columns spaced apart from each other and disposed around a periphery of the first or second heat-dissipation layer.

12. The packaging structure of claim 1, wherein the first or second heat-dissipation layer includes an insulating material.

13. A packaging structure, comprising:
a transistor disposed on a circuit board;
a resistor;
a heat-dissipation groove that accommodates the resistor; and
a light-emitting element disposed above the heat-dissipation groove,
wherein the heat-dissipation groove includes a bottom portion and a side wall portion, and
wherein the bottom portion of the heat-dissipation groove is sandwiched between the transistor and the resistor.

14. The packaging structure of claim 13, comprising:
a heat-dissipation layer disposed between the light-emitting element and the resistor that is accommodated in the heat-dissipation groove.

15. The packaging structure of claim 13, wherein the side wall portion of the heat-dissipation groove includes one or more side walls substantially perpendicular to the bottom portion.

16. The packaging structure of claim 13, wherein the side wall portion of the heat-dissipation groove includes an opening that allows a first connecting element to connect the resistor with the circuit board via the opening.

17. The packaging structure of claim 13, wherein the heat-dissipation groove further accommodates a second connecting element that connects the resistor with the light-emitting element.

18. The packaging structure of claim 13, further comprising a third connecting element that connects the transistor with the light-emitting element.

19. A packaging method, comprising:
disposing a transistor on a circuit board;
disposing a first heat-dissipation layer or a heat-dissipation groove over the transistor;
disposing a resistor over the first heat-dissipation layer or within the heat-dissipation groove; and
disposing a light-emitting element over the resistor or the heat-dissipation groove,
wherein the light-emitting element is separated from the resistor using a second heat-dissipation layer or the heat-dissipation groove.

20. The packaging method of claim 19, further comprising:
prior to disposing the light-emitting element:
configuring a first end of a first conductive element to connect with the resistor,
configuring a second end of the first conductive element to be connected to a first soldering region disposed on a surface of the second heat-dissipation layer that faces away from the resistor,
configuring a first end of a second conductive element to connect with the transistor, and
configuring a second end of the second conductive element to be connected to a second soldering region disposed on the surface of the second heat-dissipation layer that faces away from the resistor, the second soldering region being separate from the first soldering region.
